(19) United States
(12) Patent Application Publication
(10) Pub. No.: US 2021/0233783 A1
(43) Pub. Date: Jul. 29, 2021

(54) CARRIER FOR A SUBSTRATE AND METHOD FOR CARRYING A SUBSTRATE

(71) Applicants: LINDENBERG Ralph, Büdingen-Rinderbügen (DE); Applied Materials, Inc., Santa Clara, CA (US)

(72) Inventor: Ralph LINDENBERG, Büdingen-Rinderbügen (DE)

(21) Appl. No.: 15/734,539

(22) PCT Filed: Jun. 25, 2018
(86) PCT No.: PCT/EP2018/066937

§ 371 Date: Dec. 2, 2020

(51) Int. Cl. H01L 21/673; H01L 21/677; H01L 21/687

(52) U.S. Cl. CPC H01L 21/6734; H01L 21/68735; H01L 21/67712

(57) ABSTRACT

A carrier configured for holding and transporting a substrate in a transport direction in a vacuum processing system and a method for carrying a substrate in a transport direction during a deposition process in a deposition chamber with a carrier is described. The carrier includes two side edges opposing each other, a joining structure arranged between the side edges, having a flat structure comprising a plurality of apertures, each exposing the same substrate and an aperture ratio of at least 0.5, and a holding assembly configured for holding the substrate adjacent to the joining structure.

### TECHNICAL FIELD

Embodiments of the present disclosure relate to a carrier for a substrate and a method for carrying a substrate in a vacuum processing system. Embodiments of the present disclosure particularly relate to a carrier configured for holding and moving a substrate along a direction in a vacuum processing system, wherein the carrier may carry an object such as a substrate, particularly in an essentially vertical orientation. More specifically, the method described herein is adapted to carry a substrate with a carrier in a transport direction during a deposition process in a deposition chamber.

### BACKGROUND

Generally, substrate carriers are used for supporting or holding substrates to be processed and for transporting the substrates in or through processing facilities. For instance, substrate carriers are used in the display or photovoltaic industry for transporting substrates made of materials such as glass or silicon in or through processing facilities. Such substrate carriers or substrate supports may be of particular importance, especially if they are used for extremely thin substrates which should not warp during processing.

The substrate carriers, however, is beneficially not only be designed to enable a planar substrate during processing, but also to be used in high-performance systems and not let the complexity of the systems become excessive at high processing speeds.

Accordingly, it would be beneficial to improve a substrate carrier with respect to a more favorable trade-off between system complexity on one hand, and system performance and substrate quality on the other.

### SUMMARY

According to an aspect, a carrier configured for holding and transporting a substrate in a transport direction in a vacuum processing system is provided. The carrier includes two side edges opposing each other; a joining structure arranged between the side edges, having a flat structure comprising a plurality of apertures exposing the substrate, and a holding assembly configured for holding the substrate adjacent to and distant from the joining structure.

According to another aspect of the present disclosure, a carrier configured for holding and transporting a substrate in a transport direction in a vacuum processing system is provided. The carrier includes: two side edges opposing each other, a joining structure or at least one joining structure arranged between the side edges, having a flat structure including a plurality of apertures exposing each the same substrate and an aperture ratio of at least 0.5, and a holding assembly configured for holding the substrate adjacent to the joining structure.

According to another aspect of the present disclosure, a method for carrying a substrate in a transport direction during a deposition process in a deposition chamber with a carrier is provided. The carrier includes: two side edges opposing each other, a joining structure or at least one joining structure arranged between the side edges, having a flat structure including a plurality of apertures exposing each the same substrate and an aperture ratio of at least 0.5, and a holding assembly configured for holding the substrate adjacent to the joining structure.

The method includes electrostatically or magnetically chucking the substrate to a support surface of the holding assembly, e.g. at at least one of the side edges, or mechanically attaching the substrate to at least one of the side edges.

The device and the method of the present disclosure provide a substrate carrier with improved characteristics regarding a more favorable trade-off between system complexity on one hand, and system performance and substrate quality on the other, and allow for carrying a substrate during a deposition process in a deposition chamber with a higher transport capacity without any loss in substrate quality or even with an improved substrate quality.

Further aspects, advantages and features of the present disclosure are apparent from the dependent claims, the description and the accompanying drawings.

### BRIEF DESCRIPTION OF THE DRAWINGS

So that the manner in which the above recited features of the present disclosure can be understood in detail, a more particular description of the present disclosure, briefly summarized above, may be had by reference to typical embodiments. The accompanying drawings relate to embodiments of the present disclosure and are described in the following:

FIG. 1 shows a perspective view of a carrier with a joining structure, wherein an aperture of the joining structure has a polygonal boundary configured as a triangle, according to embodiments described herein;

FIG. 2 shows a perspective view of detail A shown in FIG. 1, wherein the transition between the joining structure and a holding bar is illustrated, according to embodiments described herein;

FIG. 3A shows a front view of a joining structure, wherein an aperture of the joining structure has a polygonal boundary configured as a rectangle, according to embodiments described herein;

FIG. 3B shows a front view of a joining structure, wherein an aperture of the joining structure has a circular or a meandered boundary, according to embodiments described herein;

FIG. 4A shows a schematic front view of a carrier, wherein two joining structures are arranged one behind the other and spaced apart from each other, according to embodiments described herein;

FIG. 4B shows a sectional view along the line BB shown in FIG. 4A according to embodiments described herein, wherein the substrate is fixed to the carrier at a holding bar;

FIG. 4C shows a sectional view along the line BB shown in FIG. 4A according to embodiments described herein, wherein the substrate is fixed to the carrier at a supplementary support structure; and

FIG. 5 shows a flow chart of a method for carrying a substrate in a transport direction during a deposition process in a deposition chamber with a carrier.

### DETAILED DESCRIPTION OF EMBODIMENTS

Reference will now be made in detail to the various embodiments of the present disclosure, one or more examples of which are illustrated in the figures. Within the following description of the drawings, the same reference numbers refer to the same components. Generally, only the differences with respect to individual embodiments are described. Each example is provided by way of explanation and is not meant as a limitation of the present disclosure. Features illustrated or described as part of one embodiment can be used on or in conjunction with other embodiments to yield yet a further embodiment. It is intended that the description includes such modifications and variations.

The following sections explain or define some terms and expressions that have specific meanings in this document.

The term “vertical direction” or “vertical orientation” is understood to distinguish over “horizontal direction” or “horizontal orientation”. That is, the “vertical direction” or “vertical orientation” relates to a substantially vertical orientation. The vertical direction can be substantially parallel to the force of gravity. The vertical direction may deviate from being parallel to the force of gravity by e.g. +−15°.

The term “substantially” as used herein may i) include or refer to the exact value, quantity or meaning of the characteristic denoted with “substantially”, or ii) may imply that there is a certain deviation from the characteristic denoted with “substantially”. For instance, the term “substantially vertical” refers either to an exact vertical position, or to a position which may have certain deviations from the exact vertical position, such as a deviation of about 1° to about 15° from the exact vertical position.

The terms magnetic levitation as used within the embodiments described herein can typically be characterized as a concept of an object such as a substrate carrier being suspended and moved with no support other than magnetic fields. Magnetic force is used to counteract the effect of gravitational force and to move and/or transport the object.

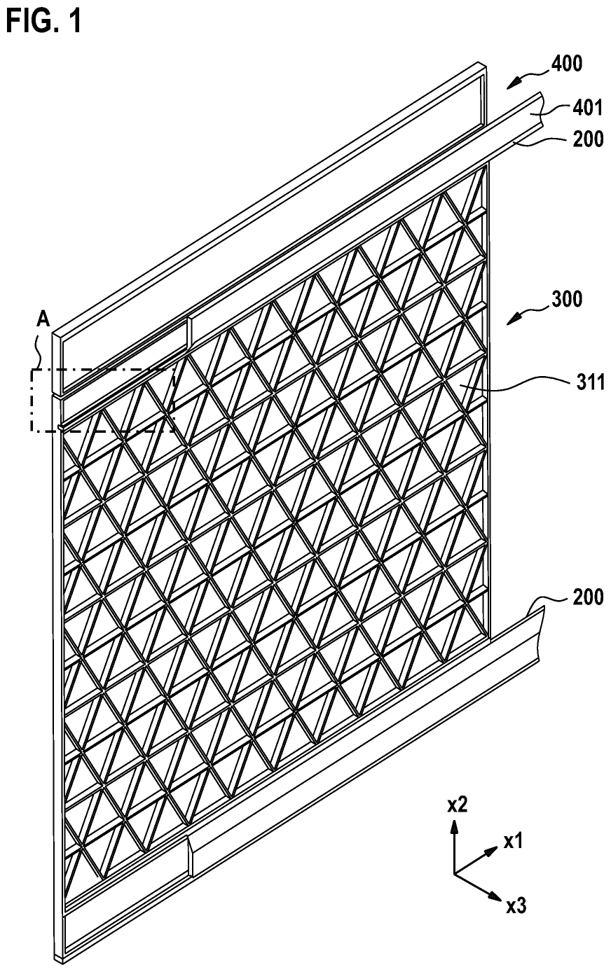

FIG. 1 shows a perspective view of a carrier 100. Details explained with illustrative reference to FIG. 1 should not be understood as limited to the elements of FIG. 1. Rather, those details may also be combined with further embodiments explained with illustrative reference to the other figures.

The carrier 100 may be designed as a device being able to carry one substrate 110 or more substrates in or through a processing installation, e.g. a processing chamber, a processing line, or a processing area. The carrier 100 may provide a sufficient strength to hold and support a substrate 110. In particular, the carrier 100 may be adapted for holding and supporting a substrate 110 during a deposition process, especially a vacuum deposition process. For instance, the carrier 100 may be adapted to vacuum conditions by being made from a suitable material having e.g. low outgassing rates, and/or a stable design including a corresponding mechanical rigidity for withstanding pressure changes. The carrier 100 may provide equipment for fixing the substrate 110, or fixing the substrate 110 to a defined extent, e.g. at some sides of the substrates, such as a clamp, an electrostatic chuck or a magnetic chuck.

According to some embodiments, the carrier 100 may be adapted for carrying a thin film substrate and/or the equipment for fixing the substrate 110 may be adapted for a thin film substrate. In some embodiments, the carrier 100 may be adapted for carrying one or more substrate(s) including a foil, glass, metal, an insulating material, Mica, polymers, and the like.

In some examples, the carrier 100 may be used for PVD deposition processes, CVD deposition process, substrate structuring edging, heating (e.g. annealing) or any kind of substrate processing. Embodiments of the carrier 100 as described herein are particularly useful for non-stationary, i.e. continuous substrate processing of the substantially vertically oriented substrates. The skilled person will understand that the carrier 100 may also be used in a stationary process and/or in a process with horizontally oriented substrates.

The carrier 100 may be configured for holding and transporting a substrate 110 in a transport direction x1 in a vacuum processing system and may include: two side edges 200 opposing each other, a joining structure 300 or at least one joining structure arranged between the side edges 200, having a flat structure including a plurality of apertures 310-313 exposing each the same substrate 110 and an aperture ratio of at least 0.5, or at least 0.6 and a holding assembly 400 configured for holding the substrate 110 adjacent to the joining structure 300.

According to embodiments of the present disclosure, the joining structure 300 connects and/or joins two opposite side edges of the carrier 100. The joining structure provides structural integrity to the carrier. Further, the aperture ratio of the joining structure, i.e. having a plurality of apertures allow for a back side heating of the substrate. Further, the back side heating can advantageously be realized by having the joining structure distant from the substrate. Shadowing can be reduced. The substrate is supported at one or more edges of the carrier, for example and upper edge and a lower edge. As described below, further support elements for the substrate may be provided. Yet, the joining structure, e.g. the joining structure connecting an upper and a lower bar of the carrier, is distant from the substrate.

The two side edges 200 of the carrier 100 may be arranged opposing each other in a holding direction x2 which is lateral or substantially perpendicular to the transport direction x1. The side edges 200 may be designed as additional elements, for example side-bars, which enclose the periphery of the carrier 100, or may be embedded in the carrier 100, e.g. as parts of the carrier 100.

A coordinate system, especially a Cartesian coordinate system or possibly an inclined coordinate system, can be formed by i) the transport direction x1, ii) a holding direction x2 that is substantially opposite to the gravitational force and substantially orthogonal to the transport direction x1, and iii) the cross direction x3 that is substantially orthogonal to the transport direction x1 and the holding direction x2. For embodiments described herein, the cross direction x3 is substantially orthogonal to a planar carrier 100 surface and/or a surface of a planar substrate 110 transported by the carrier 100, which in turn is oriented substantially parallel to the transport direction x1 and the holding direction x2.

The terms “lateral range”, “lateral extent” or “lateral area” are understood as a range, an extent or an area along a plane substantially perpendicular or orthogonal to the cross direction x3.

The substrate 110 may be a large-area substrate having a size of 0.5 m² or more, more particularly 1 m² or more, or even 5 m² or 10 m² or more. For example, the substrate 110 may be a large-area substrate for display manufacturing.

In the present disclosure, a large area substrate can be GEN 4.5, which corresponds to about 0.67 m² substrates (0.73×0.92 m), GEN 5, which corresponds to about 1.4 m² substrates (1.1 m×1.3 m), GEN 6, GEN 7, GEN 7.5, which corresponds to about 4.29 m² substrates (1.95 m×2.2 m), GEN 8, GEN 8.5, which corresponds to about 5.7 m² substrates (2.2 m×2.5 m), or even GEN 10, which corresponds to about 8.7 m² substrates (2.85 m×3.05 m) or GEN 10.5. Even larger generations such as GEN 11 and GEN 12 and corresponding substrate areas can similarly be implemented.

The joining structure 300 may be designed as a substantially flat or planar structure or body with maximum extent in a plane or an area substantially perpendicular to the cross direction x3. The joining structure 300 can be made of a material which has a low desorption in vacuum, especially of a metal or a metal alloy or any other material with beneficial desorption properties.

The lateral area of the joining structure 300 may have a plurality or multitude of apertures 310-313, i.e. openings or holes distributed over the lateral range of the lateral area, which may be viewed as material cut-outs or material gaps. With respect to the apertures, the term “plurality” refers to a number that is larger than 10, or 20, or 50 apertures.

The total area of apertures (cumulated area of apertures distributed over the lateral range of the support structure) is of a size which has a specific ratio with respect to the total lateral extent of the support structure. This ratio is called aperture ratio. In other words, the aperture ratio represents a ratio of a cumulative aperture area to a total area of the support arrangement, e.g. over the lateral range of the support arrangement.

The aperture ratio of the joining structure 300 is configured to be larger than a predefined threshold, i.e. threshold value. The threshold can be smaller than 0.95 and/or can be larger than 0.7, 0.8 or 0.9. However, a structure having i) a single aperture, i.e. a single aperture per substrate, such as a frame that is hollow in the interior, or ii) two apertures, such as a frame with a crossbar connecting opposite corners or edges, is not a structure with a plurality of apertures according to the present disclosure, i.e. as shown as a joining structure 300. Further, the joining structure with the apertures is distant from the substrate, i.e. a substrate receiving area.

In the present disclosure, the term “holding assembly” may be understood as an assembly which may be connected to a frame portion or to side edges 200 of a substrate carrier 100. In particular, a “holding assembly” may be understood as an assembly having a plurality of substrate holding elements which are configured for substantially vertically holding and supporting a large area substrate as described herein. In particular, the substrate holding elements may be arranged and configured for contacting at least a portion of an outer perimeter edge 200 of a large area substrate as described herein.

The holding assembly 400 may include i) a holding unit that can be placed on either side edge 200 or at the lateral area of the joining structure 300, or ii) a plurality of holding units that can be distributed along either side edge 200 and/or over the lateral area of the joining structure 300. The holding assembly 400 may include more than 10 substrate holding units, which are arranged along either side edge 200 or over the lateral area of the joining structure 300. For example, the substrate holding assembly 400 may include more than 16 substrate holding units, particularly more than 24 substrate holding units. For instance, the substrate holding assembly 400 may include 8 substrate holding units arranged at the upper side of the frame; and 8 substrate holding units arranged at the bottom side of the frame. Such a design may be beneficial for effectively reducing or preventing bending or bulging of the substrate supported by the holding assembly 400.

The design wherein the joining structure 300 has a flat structure including a plurality of apertures 310-313 exposing each the same substrate 110 may express that one and the same substrate 110 has such a lateral extent that substantially all or at least most of the openings of the joining structure 300 are above or close to this substrate 110. Another substrate or plurality of substrates are not affected by the apertures 310-313. Thus, directing a thermal radiation to the joining structure 300 may enable to heat up this substrate 110 without directly exposing the substrate 110 to the radiation.

The design, wherein the joining structure 300 has an aperture ratio exceeding a predefined threshold that particularly has a value of 0.8, advantageously enables uniform heat and/or temperature distribution along the lateral area of the substrate 110 with low heat loss, i.e. low heat absorption by the joining structure 300, and at the same time enables a high mechanical stability of the joining structure 300. A conventional carrier of a kind having along the lateral extent of the carrier a closed, sealed surface, i.e. a surface without openings, would not permit efficient heating of the substrate 110 by radiation from the back side. A conventional carrier of a kind with only one opening, i.e. with a peripheral frame, would have considerably less mechanical stability.

Thus, as compared to conventional approaches, the design of the present carrier 100 and especially of the joining structure 300 may improve the permeability of the carrier 100 to thermal radiation, thus enabling to heat the substrate 110 from a direction or space area opposite to that of the particle movement effecting substrate deposition, while at the same time having a high mechanical stability. This means that substrate heating and substrate deposition can be carried out simultaneously without these processes interfering with each other and without measures having to be taken to prevent mutual interfering of these processes. This has the advantage of shortening processing time to improve the system performance without increasing the complexity of the system.

According to embodiments described herein, each aperture 310-313 may be continuously circumferentially edged or bounded. That means that an observer, positioned at a center of gravity of the aperture area, who rotates 360° about his own axis sees a surrounding closed frame or border.

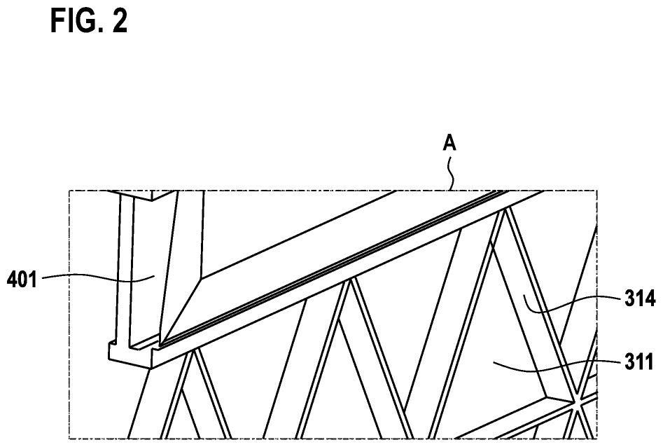

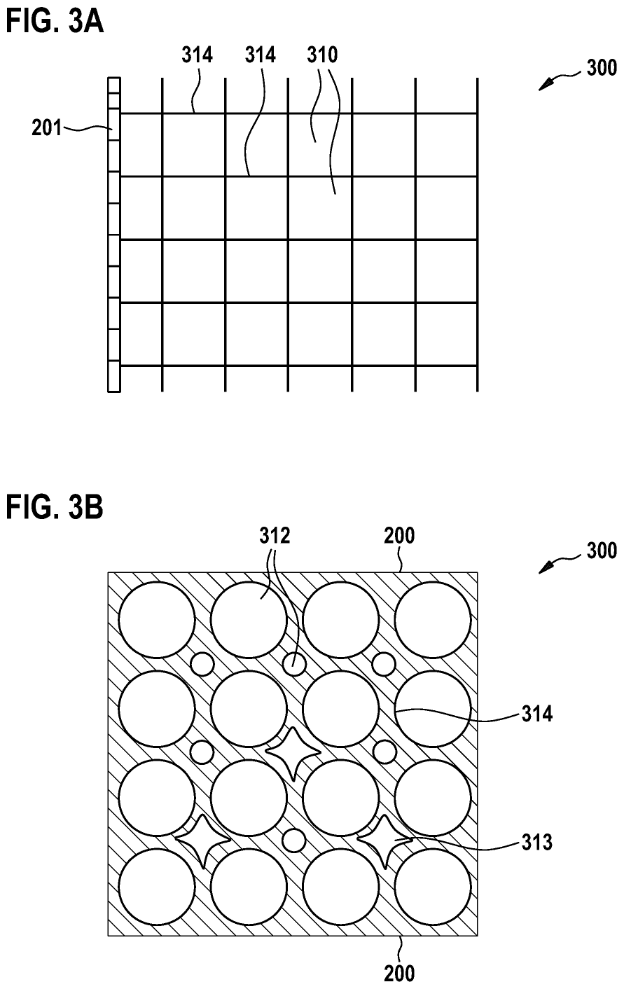

An aperture or each aperture may have a curved or meandered boundary 314, as shown for example in FIG. 2, or a polygonal boundary 314, as shown for example in FIG. 1 or 3A, and may be configured to expose the substrate 110, particularly also the back side of the substrate, to a space inside a processing chamber of the vacuum processing system. Exposing the substrate 110 to the space inside a processing chamber enables to heat the substrate 110 and to achieve uniform heat and/or temperature distribution along the lateral area of the substrate 110 with low heat loss.

FIG. 2 shows a perspective view of detail A shown in FIG. 1, wherein the transition between a joining structure 300 and a holding bar 401 is illustrated. Details explained with illustrative reference to FIG. 2 should not be understood as limited to the elements of FIG. 2. Rather, those details may also be combined with further embodiments explained with illustrative reference to the other figures.

Details of the holding assembly 400 that is configured for substantially vertically holding and supporting a large area substrate as described herein can be seen in FIG. 2 in combination with FIG. 1. In particular, substrate holding elements of the holding assembly 400 may be arranged at the two side edges 200 and configured for contacting an outer perimeter edge of the substrate 110. At least one substrate holding unit on each of the two side edges 200 may include an edge contacting surface configured for contacting the corresponding edge of the substrate 110 and defining a contact position. Further, one substrate holding unit on each of the two side edges 200 may be provided with a force element configured for applying a holding force for holding the substrate 110. For example, the force element may be a spring element. A holding unit may additionally or alternatively provide von der Waals forces for holding.

According to embodiments described herein, the holding assembly 400 may include at least one holding bar 401 for fixing the substrate 110 to the carrier 100, the holding bar 401 being arranged at at least one of the side edges 200. In particular, a holding bar 401 can be arranged at each of the side edges 200.

According to embodiments described herein, the holding assembly 400 may include a mechanical support assembly mounted on at least one of the holding bars 401, especially at both holding bars 401. The holding assembly 400 may include a plurality of clamps, with a number of clamps attached to at least one holding bar 401, especially along the holding bar 401, to hold the substrate 110 on the holding bar 401.

According to embodiments described herein, the holding assembly 400 may include an electrostatic or magnetic chuck assembly and/or a support surface for supporting the substrate 110. The electrostatic or magnetic chuck assembly may be disposed at the support surface and may include a chuck zone or a plurality of separately arranged chuck zones. According to yet further embodiments, which can be combined with other embodiments described herein, an electrostatic chuck can be provided, for example, at least in a partial area of the glass. According to yet further additional or alternative modifications, a gecko chuck can be provided, for example, at least in a partial area of the glass. A gecko chuck is a chuck that includes a dry adhesive for chucking, e.g. a synthetic setae material. Chucking is conducted with Van der Waals forces. The adhesive capabilities of the dry adhesive, specifically of the synthetic setae material, can be related to the adhesive properties of a gecko foot.

According to embodiments described herein, the chuck assembly and/or the support surface may be arranged at or may be part of one or of each of the holding bars 401. The electrostatic or magnetic chuck assembly may be disposed at the support surface and/or may include a chuck zone or a plurality of separately arranged chuck zones providing a grip force such that the substrate 110 is held or fixed at the support surface. The chuck zones may be distributed within the support surface in a predetermined pattern. Further, the chuck zones may be independently controllable. For example, the chuck zones can be independently powered and de-powered, and/or the grip force to be generated by each of the chuck zones may be independently controlled.

According to embodiments described herein, the holding assembly 400 may be designed not to have a frame portion in the transport direction x1, particularly not to have a frame portion in the transport direction that extends over the dimension of the substrate in the transport direction. A frame portion according to some embodiments, which can be combined with other embodiments described herein, provides a portion of the carrier outside a substrate receiving area. The holding assembly, particularly a holding bar, may comprise a substrate receiving area that may be understood as a portion of the holding assembly adapted for supporting the substrate. For example, a frame portion outside the substrate receiving area can be configured to support the carrier and/or drive the carrier within a processing system. For example, a frame portion can be contacted by a robot or transport mechanism without getting in contact with a substrate, i.e. the thin glass plate.

FIG. 3A shows a portion of a joining structure 300. The joining structure includes apertures 310 and polygonal boundaries 314, e.g. configured as a rectangle. For example, the boundaries 314 can be provided by a wire. In the case of a wire, a side support 201 may be provided. The side support can provide increased stiffness to a wire structure. The side support is according to typical embodiments provided in the substrate receiving area. For example, a substrate supported by a carrier may overlap with a side support or may exceed over the side support, e.g. in the case the substrate dimension in transport direction is larger than the carrier dimension in the transport direction.

According to embodiments, which can be combined with other embodiments described herein, particularly when the carrier and the substrate have essentially the same length in transport direction, edge exclusion elements may be provided at the one or more side supports 201. Further, additionally or alternatively, edge exclusion elements may be provided at an upper edge and or a lower edge, e.g. at a holding bar 401.

A holding bar 401 as described herein, e.g. an upper and a lower holding bar, provide a support surface for outer edge portions of the substrate. The joining structure is distant from the substrate. The holding bar, thus, holds and/or supports the substrate. Additionally, according to optional modification, a holding bar may also include a substrate fixation element, such as a clamp or a gecko pad.

According to embodiments described herein, the two side edges 200 of the carrier 100 and/or holding bars 401 of the holding assembly 400 may be arranged opposing each other in the holding direction x2. Carriers according to embodiments of the present disclosure may have the effect that successive substrates can be transported in greater proximity to each other, which advantageously enables increasing the transport and processing density of the substrates, to improve system performance. The arrangement may also have the effect that the carrier 100 does not exceed or extend beyond the substrate 110 in the transport direction x1, thus allowing to reduce coating on the carrier 100 during the deposition process.

Previously known carriers could be provided by a frame surrounding a substrate receiving area, wherein the substrate was clamped to clamps connected to the frame and the substrate was substantially unsupported over the substrate receiving area. Such a frame was provided on four sides of a rectangular large area substrate. Further, previously known carriers have, for example, been provided as electrostatic chucks, wherein a solid surface has been provided to have the substrate attached to the solid surface. An area was provided surrounding the rectangular substrate receiving area. A heater external to the carrier could not heat the substrate from the back side, as the glass was attached to the solid surface with the back side. Both options suffered from a side frame portion, i.e. vertical frame portions for a vertically oriented substrate. The side frame portion increased the distance of two substrates transported through a processing system. Further, the side frame portions have likely been subject to unwanted depositions on the carrier. Such unwanted depositions resulted in a frequent carrier cleaning.

According to embodiments of the present disclosure, a carrier is provided, which is “frameless” in a sense that no or no significant side frame portions extending over a substrate receiving area are provided. For example, the length of the carrier in forward direction can be substantially the same length as the length of a large area substrate in one of the substrate size generations defined herein. A joining structure having a mesh or lattice structure can be provided between two holding bars, e.g. an upper holding bar and a lower holding bar. The holding bars may serve to transport the carrier. The joining structure is a structure with a plurality of openings, e.g. 10 or more openings. The joining structure provides, for example, mechanical strength to the carrier, particularly in the absence of side frame portions of a frame carrier. The joining structure is provided distant from a plane of the substrate receiving area in the carrier. Accordingly, a shading effect of a back side heating (external to the carrier) can be reduced to allow for uniform back side heating. Accordingly, advances of known frame carriers (as described above) and of known E-chuck carriers can be combined by a frameless carrier according to embodiments described herein.

FIGS. 3A-3B show front views of joining structures. An aperture 310 of the joining structure 300 shown in FIG. 3A has a polygonal boundary 314 configured as a rectangle. An aperture 312, 313 of the joining structure 300 shown in FIG. 3B has a circular or a meandered boundary 314. Details explained with illustrative reference to FIGS. 3A-3B should not be understood as limited to the elements of FIGS. 3A-3B. Rather, those details may also be combined with further embodiments explained with illustrative reference to the other figures.

According to embodiments described herein, the boundary 314 of an aperture 310, 311 can be formed as a polygon with at least three corners, especially as a polygon with three corners as shown in FIG. 1, or a polygon with four corners as shown in FIG. 3A. For a polygon, especially a quadrangle, opposite sides can be substantially the same length; eventually all sides of a polygon can have the same length. For example, 3 to 6 corners may be provided for the aperture. A boundary of an aperture can be formed as a polygon with at least three corners, especially as a polygon with three to six corners, wherein particularly polygon side lengths are the same or about the same with respect to each other.

According to embodiments described herein, the joining structure 300 may have a lattice structure or a mesh-shaped design. Particularly, a lattice is understood as a flat panel made up of wide crossed thin strips of material that may be rigid, while for example a mesh is understood as a structure made of connected strips of material that may be flexible or ductile. The lattice can for example be a grating that is milled from a plate, while a mesh can for example be made of braided or woven wire, and particularly may have stitches or loops. Similarly, the joining structure 300 may possibly have a grid structure.

According to embodiments described herein, the joining structure 300 may be formed at least in some regions by a uniform and/or periodic sequence of apertures 310-313, as shown in FIGS. 3A, 3B. Advantageously, such a regular structure allows a homogeneous heating of the substrate 110.

According to embodiments described herein, the carrier 100 may include at least two joining structures, in particular three or four joining structures or a plurality of more than four joining structures. The at least two joining structures can be arranged side by side. Additionally or alternatively, two or more joining structures may be provided one over the other, i.e. adjacent to each other in holding direction, Having a different or separate joining structure at one or more sides (in transport direction) or at an upper and/or lower edge of the carrier may allow for influencing a uniformity of a substrate heating. Thus, two or more joining structures may be provided for better temperature uniformity of a substrate.

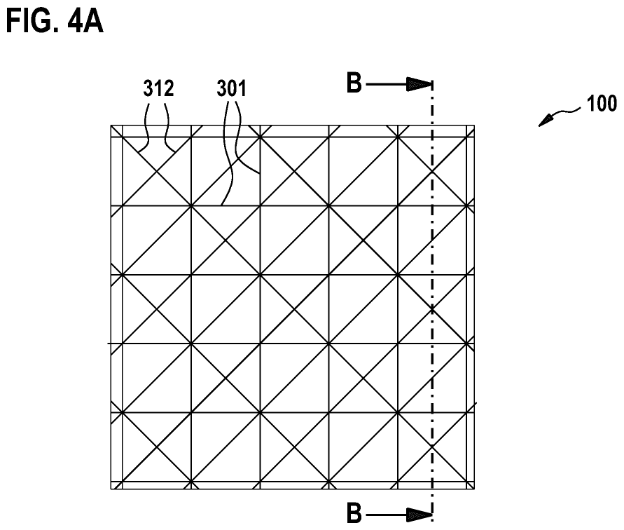

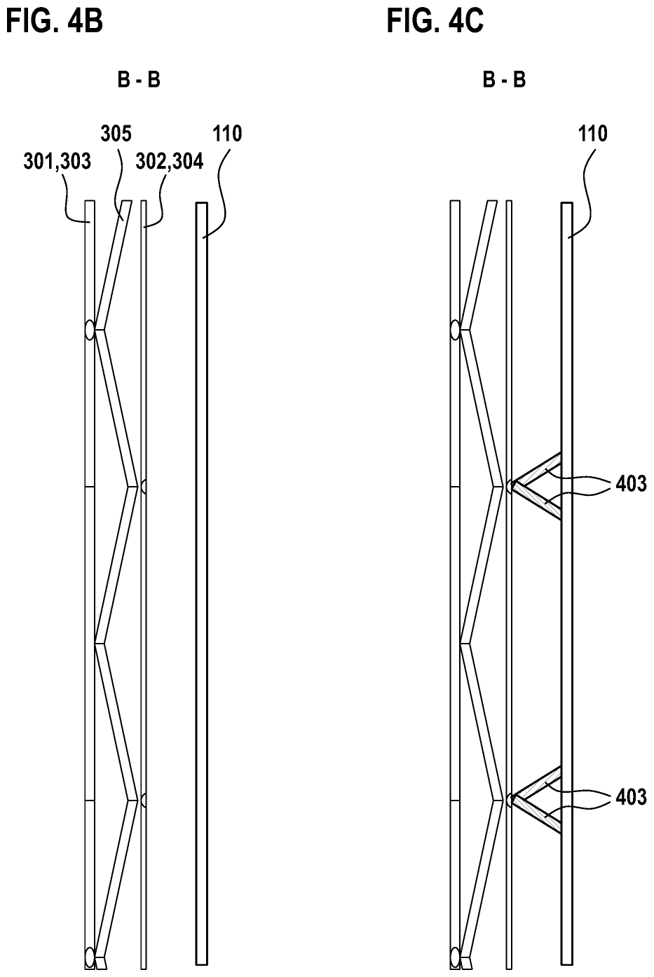

According to embodiments described herein, the joining structures may be arranged side by side. For example, joining structures can be spaced or directly adjacent to one another. Additionally or alternatively, the joining structures can be arranged in a layer-shaped structure including at least two layers 303, 304 (see e.g. FIG. 4B). The two or more layers can be provided one on top of each other, in particular substantially parallel. A first layer and a second layer can also be adjacent to each another, i.e. next to each other in a view shown in FIG. 4A. A first layer and a second layer can be spaced for example at a distance of at least 5 mm and/or less than 40 mm. Combinations of layers arranged side by side and one on top of the other can also be provided.

According to some embodiments, a first joining structure can have a first polygon pattern, for example, a first group of rectangles. A second joining structure can have a second polygon pattern, for example, a second group of rectangles. The first polygon pattern can have an orientation that is moved by an angle, rotated or flipped as compared to the second polygon pattern. Rectangles of a first joining structure are rotated as compared to rectangles at another joining structure. The angle can be at least 10°, at least 30° and/or less than 60°. For example, the angle can be about 45°.

For example, a carrier may have two or more joining structures arranged coplanarly side by side, next to each other, with outer lateral joining structures having lattices with vertical orientation and with the lattice in the middle being inclined by an angle of about 45° in relation to the outer lateral lattices. This combined structure may provide an improved temperature uniformity when the substrate is heated.

A lattice with vertical orientation is understood as a lattice having apertures with two opposite edges in a substantially vertical orientation, and an inclined lattice is understood as obtained by tilting or rotating a vertical lattice around an angle not equal to zero.

A carrier may include a lateral arrangement of joining structures including to the left a joining structure with in an inner layer, in the middle a joining structure in an external layer, and to the right two joining structures arranged one behind the other in an inner layer and an external layer.

Arrangements of laterally spaced joining structures in mutually spaced planes with different lattice orientations makes it possible to flexibly adapt the distribution of the heating radiation on the substrate 110. Additionally or alternatively, adaptation of the mechanical stability of the carrier 100 to the technical requirements of the respective application can be provided. The adjustment or optimization process can be carried out using computer-aided simulations by varying parameters such as mesh density, size of openings, lattice orientation, distances between the joining structures or material parameters such as thermal or electrical conductivity of the lattices.

Such an adjustment or optimization process may result in considerably reducing i) shadowing effects of the carrier 100 and ii) substrate temperature uniformities, for example to less than 10% of the mean or average substrate temperature, that may be about 80° to 120° C.

According to embodiments described herein, the joining structure 300 or each joining structure can be formed i) by a milling process, i.e. as a milled structure, or ii) as a bent wire structure. Milled structures are shown in FIGS. 1, 3a, and bent wire structures are shown in FIGS. 3A, 4A. Combinations of milled structures and wire structures are also beneficial. Alternatively to a milling process, the grid or lattice of a joining structure 300 can also be cut or molded into a thin plate.

According to embodiments described herein, the joining structure 300 may include or essentially consist of a metal. For example, the bent wire structure may include or essentially consist of aluminum. For example, a milled structure may include steel. This provides a low desorption in the vacuum, and/or a low weight and/or good mechanical stability.

The bent wire structure can be made of wires with a diameter of at least 2 mm and/or less than 5 mm, particularly about 3 mm. This design provides a reasonable compromise between good mechanical stability and uniform distribution of the heating radiation on the substrate 110. Based on design parameters as specified above, the joining structure 300 has good thermal permeability and homogeneous thermal irradiation of the substrate 110.

FIG. 4A shows a schematic front view of a carrier 100, and FIGS. 4B-4C show sectional views along the line BB shown in FIG. 4A. Details explained with illustrative reference to FIGS. 4A-4c should not be understood as limited to the elements of FIGS. 4A-4c. Rather, those details may also be combined with further embodiments explained with illustrative reference to the other figures.

According to embodiments described herein, joining structures arranged one on top of another may be interconnected by a connecting assembly 305. Said connecting assembly 305 may include zig-zag-shaped or meander-shaped, particularly wire-shaped or strip-shaped, connecting elements that can especially be made of a material with low desorption in vacuum such as a metal, in particular aluminum or steel.

FIG. 4A shows two joining structures that are arranged one behind the other and spaced apart from each other. From FIG. 4A in combination with FIGS. 4B-4c that show sectional views along the line BB of FIG. 4A, the zig-zag- and strip-shaped connecting elements 305 connecting the two joining structures that are arranged one behind the other can be seen.

Such a connecting assembly 305 enables a mechanically stable and optionally elastic connection between the joining structures arranged in spaced-apart planes and enables good mechanical stability paired with good permeability to thermal radiation for the composite arrangement and thus uniform irradiation of the substrate 110.

According to embodiments described herein, the holding assembly 400 may include a body that is arranged between the side edges 200, wherein the body may include the support surface. As shown in FIG. 4C, said body may be designed as a supplementary support structure 403 for the substrate 110 that is implemented as two or more legs. According to embodiments of the present disclosure, the substrate can be fixed in the carrier in an edge area, e.g. only in an edge area. For example, the edge area can be provided by a holding bar 401 (see FIG. 1, such as a top holding bar). Optionally a supplementary support, such as legs 403 can be provided. Additionally, any kind of chucking element described herein may be used in additional or instead of the legs 403.

The legs 403 may be designed as a horizontal V which is open towards the substrate 110, with the tip of the V braced against the most proximal joining structure 302 and the front surface of the feet of the V touching the substrate 110 and exerting a clamping force on the substrate 110, for example on an electrostatic or electrodynamic basis.

The supplementary support 403 structure can also be designed as a horizontal cone opened towards the substrate 110, with the tip of the cone braced against the most proximal joining structure 302 and a ring shaped front surface of the cone aperture touching the substrate 110 and exerting a clamping force on the substrate 110, similarly to the legs. The cone may have a mesh-shaped structure to improve permeability to heat radiation.

Such a supplementary support structure 403 enables a stable support of the substrate 110 in relation to the joining structure 302 with only minor shading effects with respect to the heating radiation directed to the substrate 110.

According to embodiments described herein, the joining structure 300 is arranged at a distance from the substrate 110, in particular at a distance of at least 10 mm and/or less than 60 mm, especially at a distance of about 10, 20, 30 or 40 mm. In said distance range or at said distances, in combination with wire diameters of 1, 2, 3, or 4 mm, the heat radiation diffraction effects at the joining structure 300, i.e. the superposition of half-shadow components generated by the lattice (grating), can be designed in such a way that largely uniform heat radiation of the substrate 110 is produced with only minor intensity and/or temperature fluctuations on the substrate 110.

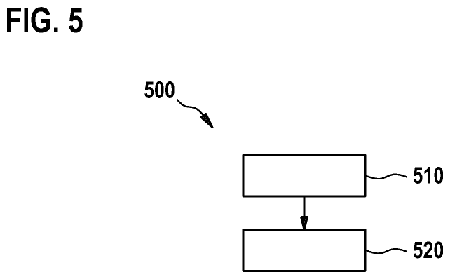

FIG. 5 shows a flow chart of a method 500 for carrying a substrate 110 in a transport direction x1 during a deposition process in a deposition chamber with a carrier such as one shown for example in the figures. The method may include in box 510 providing a carrier 100 comprising two side edges 200 opposing each other, a joining structure 300 arranged between the side edges 200, having a flat structure comprising a plurality of apertures exposing each the same substrate and an aperture ratio of at least 0.5, for example, at least 0.7 or at least 0.8, and a holding assembly 400 configured for holding the substrate 110 adjacent to the joining structure 400. The method may further include in box 520 supporting the substrate 110 to at least one of the side edges 200.

The method further may include in box 520 electrostatically or magnetically chucking the substrate 110 to a support surface of the holding assembly, between the side edges or at at least one of the side edges, or mechanically attaching the substrate to at least one of the side edges.

Carrying the substrate 110 with the carrier 100 may include holding the carrier 100 in the holding direction x2 and/or moving the carrier 100 in the transport direction x1.

The carrier 100 may be held by exerting a magnetic force on the carrier 100 in the holding direction x2, and moving the carrier 100 may be enabled by exerting a magnetic force on the carrier 100 in the transport direction x1. Both forces in the holding direction x2 and in the transport direction x1 may be exerted by a magnetic levitation system.

According to embodiments of the present disclosure, which can be combined with other embodiments described herein, a frameless carrier can be transported in a vacuum processing system with a mechanical transport system, such as a roller based transport system or a belt driven transport system. Additionally or alternatively, a contactless transport system, such as a magnetic levitation system, can be provided for transportation of a frameless carrier. An upper edge (or upper bar) and/or a lower edge (or lower bar) of the frameless carrier can be provided as an interface to the carrier transport system.

The deposition process may be facilitated by heating the substrate 110 during the deposition process. The process of heating the substrate 110 may be performed by heating of a substrate surface that is opposite a substrate surface on which material is deposited.

This written description uses examples to disclose the disclosure, including the best mode, and also to enable any person skilled in the art to practice the described subject-matter, including making and using any apparatus or system and performing any incorporated methods. Embodiments described herein provide an improved method and carrier for holding and transporting a substrate in a transport direction in a vacuum processing system with an excellent trade-off between system complexity on the one hand, and system performance and substrate quality on the other. While various specific embodiments have been disclosed in the foregoing, mutually non-exclusive features of the embodiments described above may be combined with each other. The patentable scope is defined by the claims, and other examples are intended to be within the scope of the claims if they have structural elements that do not differ from the literal language of the claims, or if they include equivalent structural elements with insubstantial differences from the literal language of the claims.

1. A carrier configured for holding and transporting a substrate in a transport direction in a vacuum processing system, comprising:
two side edges opposing each other,
a joining structure arranged between the side edges, having a flat structure comprising a plurality of apertures exposing the substrate; and
a holding assembly configured for holding the substrate adjacent to and distant from the joining structure.

2. The carrier according to claim 1, wherein the apertures are continuously circumferentially edged or bounded, or wherein the apertures each have a curved or meandered or polygonal boundary.

3. The carrier according to claim 1, wherein the boundary of an aperture is formed as a polygon with at least three corners, or wherein the boundary of an aperture is formed as a polygon with three to six corners.

4. The carrier according to claim 1, wherein the joining structure has a lattice structure or is formed in a mesh-shaped design.

5. The carrier according to claim 1, wherein the joining structure is formed at least in some regions by a uniform sequence of apertures, or wherein the joining structure is formed at least in some regions by a periodic sequence of apertures.

6. The carrier according to claim 1, wherein the carrier comprises at least two joining structures.

7. The carrier according to claim 6, wherein the at least two joining structures are arranged in a layer-shaped structure comprising at least two layers.

8. The carrier according to claim 7, wherein the layers are arranged one on top of the other.

9. The carrier according to claim 6, wherein the at least two joining structures are arranged with respect to each other rotated or flipped by an angle being at least one of a croup consisting of: not equal to 0°, 45° at least 30° and less than 60°.

10. The carrier according to claim 1, wherein the joining structure or each joining structure is formed as i) a milled structure or ii) a bent wire structure.

11. The carrier according to claim 1, wherein joining structures arranged one on top of another are interconnected by a connecting assembly, or wherein joining structures arranged one on top of another are interconnected by a connecting assembly, the connecting assembly, comprising zig-zag-shaped or meander-shaped.

12. The carrier according to claim 1, wherein the holding assembly comprises at least one of a group consisting of: an electrostatic chuck assembly, gecko chuck assembly, magnetic chuck assembly and a support surface for supporting the substrate.

13. A carrier configured for holding and transporting a substrate in a transport direction in a vacuum processing system, comprising:
two side edges opposing each other,
a joining structure arranged between the side edges, having a flat structure comprising a plurality of apertures exposing the substrate and having an aperture ratio of at least 0.6, and
a holding assembly configured for holding the substrate adjacent to the joining structure.

14. A carrier configured for holding and transporting a substrate in a transport direction in a vacuum processing system, comprising:
two side edges opposing each other, the side edges being an upper edge and a lower edge for an vertically oriented substrate;
at least one holding bar for fixing the substrate to the carrier, the holding bar being arranged at at least one of the side edges; and
a joining structure arranged between the side edges, having a flat structure comprising a plurality of apertures exposing the substrate at a back side of the substrate.

15. A method for carrying a substrate in a transport direction during a deposition process in a deposition chamber with a carrier having two side edges opposing each other, a joining structure arranged between the side edges, having a flat structure comprising a plurality of apertures, and a holding assembly configured for holding the substrate adjacent to the joining structure, the method comprising:
supporting the substrate at a support surface of the holding assembly, at at least one of the side edges and distant from the joining structure.

16. The method according to claim 15, further comprising:
heating of a substrate surface that is opposite a substrate surface, on which material is deposited.

17. The carrier according to claim 1, wherein the carrier extends, in the transport direction, to a same extent or to a lesser extent as the substrate.

18. The carrier according to claim 1, wherein the joining structure is configured to provide structural integrity to the carrier.
